(19) United States
(12) Patent Application Publication
(10) Pub. No.: US 2026/0227433 A1
(43) Pub. Date: Aug. 6, 2026

(54) Integrated Diagnostic System and Method for Health and Fitness Equipment with Bypass and Mobile App Integration

(71) Applicants: Daniel Huff Thompson, Jr., Warrenville, IL (US); Ruben Hand, Sun City, AZ (US)

(72) Inventors: Daniel Huff Thompson, Jr., Warrenville, IL (US); Ruben Hand, Sun City, AZ (US)

(21) Appl. No.: 19/044,819

(22) Filed: Feb. 4, 2025

(51) Int. Cl. G01R 27/14; A63B 24/00

(52) U.S. Cl. CPC G01R 27/14; A63B 24/0087; A63B 2225/02; A63B 2225/305

(57) ABSTRACT

The present invention provides a diagnostic system and method for health and fitness equipment, designed to bypass non-functional motor control boards and independently test key components such as drive motors, incline motors, alternators, potentiometers, and resistors. The system comprises a portable diagnostic device with multiple connection ports and a mobile application for guiding users through the diagnostic process, capturing real-time data, and generating detailed repair recommendations. The invention supports multiple health and fitness equipment types, including treadmills, ellipticals, steppers, and bikes, offering enhanced versatility. By automating diagnostics, generating professional-grade reports, and enabling predictive maintenance through trend analysis, the invention streamlines equipment troubleshooting, reduces downtime, and improves reliability. Its user-friendly design and scalable functionality make it suitable for professional technicians, gym owners, and home users, providing an efficient and comprehensive solution for maintaining and repairing health and fitness equipment.

### BACKGROUND OF THE INVENTION

### Technical Field

This invention relates generally to a diagnostic system for health and fitness equipment. This invention relates more particularly to an apparatus/device for bypassing treadmill motor control boards and diagnosing health and fitness equipment malfunctions using a mobile application.

This invention relates generally to apparatuses and devices for testing and troubleshooting health and fitness equipment components such as motors, alternators, resistors, and batteries. This method also can be used with multiple types of health and fitness equipment, including treadmills, ellipticals, steppers, and bikes. This invention relates more particularly to a portable diagnostic device and system to identify, analyze, and recommend repairs for health and fitness equipment malfunctions.

The present invention pertains to the field of diagnostic systems and methods for health and fitness equipment, particularly systems and devices used for testing, analyzing, and troubleshooting components of exercise machines, such as treadmills, ellipticals, steppers, and stationary bikes. This invention further pertains to apparatuses and methods for bypassing malfunctioning motor control boards, enabling independent component testing, and integrating real-time diagnostic functionalities through mobile applications.

This invention falls under U.S. Patent Classification Class 482: Exercise Devices, specifically those involving the testing and maintenance of electrically or mechanically powered health and fitness equipment. Additionally, aspects of the invention may align with Class 324: Electricity: Measuring and Testing, particularly in the subcategories related to diagnostic systems for evaluating electrical components, such as motors, resistors, alternators, and batteries, in powered devices.

### Background Art

In the field of health and fitness equipment maintenance and diagnostics, identifying and resolving malfunctions has traditionally been a complex and time-intensive process. Existing methods and tools rely heavily on manual testing using multimeters and similar basic diagnostic instruments. These approaches require significant technical expertise, are labor-intensive, and often fail to address the root causes of equipment failures efficiently. The lack of integration between diagnostic systems and modern technologies further limits their utility, particularly in professional settings.

Dependence on Functional Motor Control Systems: Diagnostic testing for health and fitness equipment, particularly treadmills, is often constrained by the operational state of the motor control board. When this critical component is non-functional, traditional diagnostic methods are rendered ineffective, as they rely on the treadmill's onboard systems for operation. This limits the ability of technicians to test other components, such as the drive motor, incline motor, and rollers.

Manual and Time-Consuming Testing: Current practices involve step-by-step manual testing using tools like multimeters to measure voltage, resistance, and current. These methods require expertise, are prone to human error, and are not scalable for commercial or professional use. The lack of automation in these processes further exacerbates the time and effort required to diagnose issues accurately.

Limited Compatibility Across Equipment: Existing diagnostic tools are often specific to a single type of health and fitness equipment, such as treadmills, and are not designed to accommodate other equipment types like ellipticals, steppers, or bikes. This limitation necessitates multiple tools and methods, complicating the diagnostic process for technicians and gym owners who maintain diverse equipment.

Lack of Real-Time Data and Insights: Traditional diagnostic methods provide limited feedback and often require technicians to interpret raw electrical data. There is no mechanism to automate the interpretation of diagnostic results, suggest next steps, or generate professional reports. Additionally, existing solutions do not offer trend analysis or long-term performance tracking to predict potential failures.

Absence of Integration with Modern Technology: Despite advancements in mobile and cloud-based technologies, existing diagnostic tools lack integration with apps or platforms that could streamline the diagnostic process, guide users through testing, and store historical data for analysis. This gap limits the efficiency and accessibility of diagnostic systems for both professional and home users.

The present invention addresses these challenges by introducing a comprehensive diagnostic system that bypasses the limitations of traditional tools and methods. This system represents a significant advancement in the field of health and fitness equipment diagnostics and maintenance.

Bypassing Malfunctioning Motor Control Systems: The present invention includes a physical device that bypasses the motor control board and user interface, enabling independent testing of key components such as the drive motor, incline motor, and rollers. This feature allows technicians to diagnose issues even when the motor control board is non-functional, reducing downtime and improving diagnostic accuracy.

Integration with a Mobile Application: The system integrates with a mobile application that automates the diagnostic process, provides guided testing steps, captures real-time data, and generates repair recommendations. This innovation minimizes the need for manual interpretation of raw electrical data and offers a user-friendly interface for both professional and home users.

Support for Multiple Types of Health and Fitness Equipment: Unlike existing tools, the present invention is compatible with a wide range of health and fitness equipment, including treadmills, ellipticals, steppers, and bikes. This versatility eliminates the need for multiple tools and simplifies the maintenance of diverse equipment portfolios.

Automation and Reporting: The mobile application collects diagnostic data automatically and generates detailed reports, including diagnostic results, recommended repairs, and historical trends. These reports can be stored for long-term analysis or shared with customers, enhancing the professional value of the system.

Enhanced Efficiency and Accuracy: By automating key aspects of the diagnostic process and eliminating the need for manual testing, the present invention significantly reduces the time and effort required to diagnose health and fitness equipment malfunctions. Its integration with modern technologies ensures accurate and consistent results.

Predictive Maintenance Capabilities: The system includes trend analysis features that track the performance of equipment components over time, allowing users to predict and address potential failures before they occur. This proactive approach enhances the reliability and longevity of health and fitness equipment.

The present invention overcomes the limitations of traditional diagnostic systems by providing an automated, versatile, and efficient solution for health and fitness equipment diagnostics. Its ability to bypass motor control systems, integrate with mobile applications, and support multiple equipment types sets it apart from existing solutions. By addressing the challenges in the field, the present invention delivers a powerful tool for technicians, gym owners, and home users to maintain and repair health and fitness equipment with greater ease, accuracy, and efficiency.

In light of the foregoing prior art, there is a need for a comprehensive diagnostic system and method to better identify, analyze, and resolve malfunctions in health and fitness equipment efficiently and accurately, even when critical components like motor control boards are non-functional.

This system should enable automated diagnostic processes, integration with modern technologies such as mobile applications, and compatibility with multiple types of health and fitness equipment, including treadmills, ellipticals, steppers, and bikes. Such advancements would reduce reliance on manual testing methods, enhance the accuracy and speed of diagnostics, and provide users with actionable insights through intuitive reporting and trend analysis tools.

### BRIEF SUMMARY OF THE INVENTION

The present invention provides a diagnostic system and method for health and fitness equipment that overcomes the limitations of traditional diagnostic tools and techniques. The invention includes a portable diagnostic device and a mobile application that work together to bypass malfunctioning motor control boards and enable independent testing of key components, such as drive motors, incline motors, alternators, batteries, and resistors. This system is compatible with a wide range of health and fitness equipment, including treadmills, ellipticals, steppers, and bikes.

The diagnostic device integrates connection ports for DC and AC motors, probe ports for manual testing, and programmable firmware for updating diagnostic protocols. It is enclosed in a portable case for easy transport and field use. The mobile application automates the diagnostic process by guiding users through testing steps, capturing real-time operational data, and generating detailed reports with repair recommendations.

### Objects of the Invention

To enable independent testing of heath and fitness equipment components: The invention bypasses motor control boards and user interfaces, allowing direct diagnostics of drive motors, incline motors, and other critical components, even when the equipment is non-functional.

To automate the diagnostic process: By integrating with a mobile application, the system eliminates the need for manual testing and interpretation, reducing errors and saving time.

To support multiple types of health and fitness equipment: Unlike traditional tools limited to specific machines, the present invention is designed for treadmills, ellipticals, steppers, bikes, and other equipment, offering a versatile solution for technicians and users.

To provide actionable insights and reports: The system generates detailed diagnostic reports, including trend analysis and repair recommendations, which can be stored for future reference or shared with customers.

To enhance efficiency and ease of use: The combination of a portable diagnostic device and an intuitive mobile app simplifies testing and troubleshooting, making it accessible to both professionals and capable home users.

### Advantages of the Invention

Efficiency: Reduces the time and effort required to diagnose health and fitness equipment issues by automating critical steps.

Versatility: Supports a wide range of health and fitness equipment, making it a single solution for diverse diagnostic needs.

Reliability: Ensures accurate testing and minimizes human error through real-time data capture and automated guidance.

Professional Value: Provides technicians with professional-grade reports, for example industry standard metrics and parameters established by the North American Health and Fitness Trades Alliance, that enhance customer service and long-term maintenance capabilities.

Predictive Maintenance: Tracks performance trends to predict potential failures, enabling proactive repairs.

The present invention addresses the longstanding challenges of health and fitness equipment diagnostics, offering a modern, automated, and comprehensive solution that significantly improves upon existing methods. By integrating advanced hardware and software, the invention not only enhances the diagnostic process but also establishes a new standard for maintaining and repairing fitness equipment.

According to a first aspect of the invention, there is a diagnostic system for health and fitness equipment comprising a control unit configured to bypass the motor controller and user console of a treadmill, a connection module for interfacing with the treadmill's drive motor and incline motor, and a mobile application configured to display diagnostic steps, capture real-time data, and generate repair recommendations. Further features of the invention are disclosed in additional aspects.

According to one aspect of the present invention, there is a diagnostic system in the form of a user interface for inputting multimeter readings into a mobile application. An advantage of the user interface is that it simplifies the diagnostic process, reducing errors and making it accessible to both professional and home users.

According to another aspect of the present invention, there is a diagnostic system in the form of a trend analysis tool for tracking changes in motor or component performance over time. An advantage of the trend analysis tool is that it enables proactive maintenance, minimizing equipment downtime and extending its lifespan.

According to another aspect of the present invention, there is a diagnostic system in the form of a connection module for separating ports for DC and AC motor testing. An advantage of the connection module is that it supports diverse motor types, providing versatility for technicians servicing multiple health and fitness equipment models.

According to a second aspect of the invention, there is a physical diagnostic device for health and fitness equipment comprising a motor control board within a portable case, multiple connection ports for testing DC motors, AC motors, alternators, and resistors, and a data interface for transmitting real-time operational data to a mobile application. Further features of the invention are disclosed in additional aspects.

According to one aspect of the present invention, there is a diagnostic device in the form of a probe port for attaching standard multimeter probes. An advantage of the probe port is that it enhances diagnostic precision by enabling direct electrical measurements.

According to another aspect of the present invention, there is a diagnostic device in the form of a portable case for housing the motor control board and diagnostic components. An advantage of the portable case is that it provides durability and convenience, making the device easy to transport and use in field conditions.

According to another aspect of the present invention, there is a diagnostic device in the form of a breaker for providing overload protection during testing. An advantage of the breaker is that it ensures the safety of both the device and the equipment being tested, preventing damage from power surges or mis-operation.

According to a third aspect of the invention, there is a method for diagnosing health and fitness equipment malfunctions comprising bypassing the motor controller and user interface of a treadmill, independently controlling key components, transmitting real-time data to a mobile application, and generating diagnostic reports and repair recommendations. Further features of the invention are disclosed in additional aspects.

According to one aspect of the present invention, there is a method in the form of a process for generating PDF reports for providing detailed diagnostic results and repair recommendations. An advantage of this process is that it enhances communication with customers and improves record-keeping for maintenance tracking.

According to another aspect of the present invention, there is a method in the form of a testing procedure for measuring voltage drop and resistance for assessing the condition of treadmill motors. An advantage of this testing procedure is that it delivers precise and actionable data, ensuring effective repairs.

According to another aspect of the present invention, there is a method in the form of a data storage feature for saving customer-specific diagnostic reports for future reference. An advantage of the data storage feature is that it streamlines long-term maintenance planning and improves service efficiency.

The invention will now be described, by way of example only, with reference to the accompanying drawings in which:

### BRIEF DESCRIPTION OF THE SEVERAL VIEWS OF THE DRAWINGS

FIG. 1 is a perspective exploded view of the integrated diagnostic system and method for health and fitness equipment with bypass and mobile app integration according to the invention;

FIG. 2 is a perspective view of a treadmill and the integrated diagnostic system and method for health and fitness equipment with bypass and mobile app integration according to the invention; and

FIG. 3 is a flowchart of the method for diagnosing a malfunction of a health and fitness equipment of the integrated diagnostic system and method for health and fitness equipment with bypass and mobile app integration according to the invention.

### DETAILED DESCRIPTION OF THE INVENTION

The detailed embodiments of the present invention are disclosed herein. The disclosed embodiments are merely exemplary of the invention, which may be embodied in various forms. The details disclosed herein are not to be interpreted as limiting, but merely as the basis for the claims and as a basis for teaching one skilled in the art how to make and use the invention.

References in the specification to “one embodiment,” “an embodiment,” “an example embodiment,” etcetera, indicate that the embodiment described may include a particular feature, structure, or characteristic, but every embodiment may not necessarily include the particular feature, structure, or characteristic. Moreover, such phrases are not necessarily referring to the same embodiment. Further, when a particular feature, structure, or characteristic is described in connection with an embodiment, it is submitted that it is within the knowledge of one skilled in the art to effect such feature, structure, or characteristic in connection with other embodiments whether or not explicitly described.

Furthermore, it should be understood that spatial descriptions (e.g., “above,” “below,” “up,” “left,” “right,” “down,” “top,” “bottom,” “vertical,” “horizontal,” etc.) used herein are for purposes of illustration only, and that practical implementations of the structures described herein can be spatially arranged in any orientation or manner.

Throughout this specification, the word “comprise,” or variations thereof such as “comprises” or “comprising,” will be understood to imply the inclusion of a stated element, integer or step, or group of elements integers or steps, but not the exclusion of any other element, integer or step, or group of elements, integers or steps.

Index of Labelled Features in Figures. Features are listed in numeric order by Figure in numeric order.

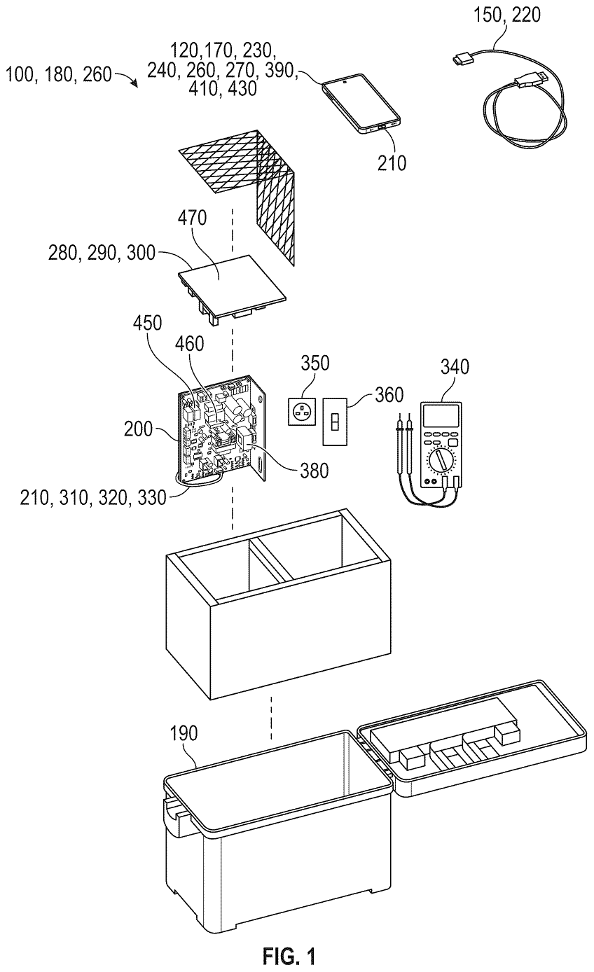

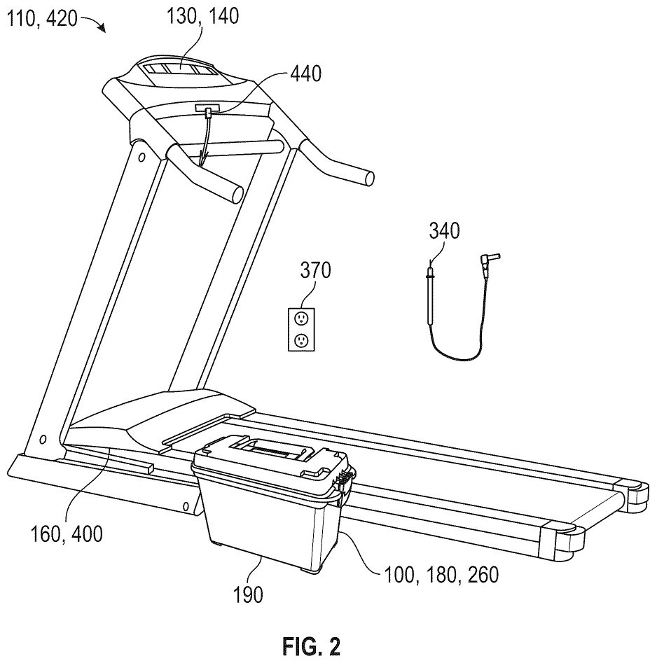

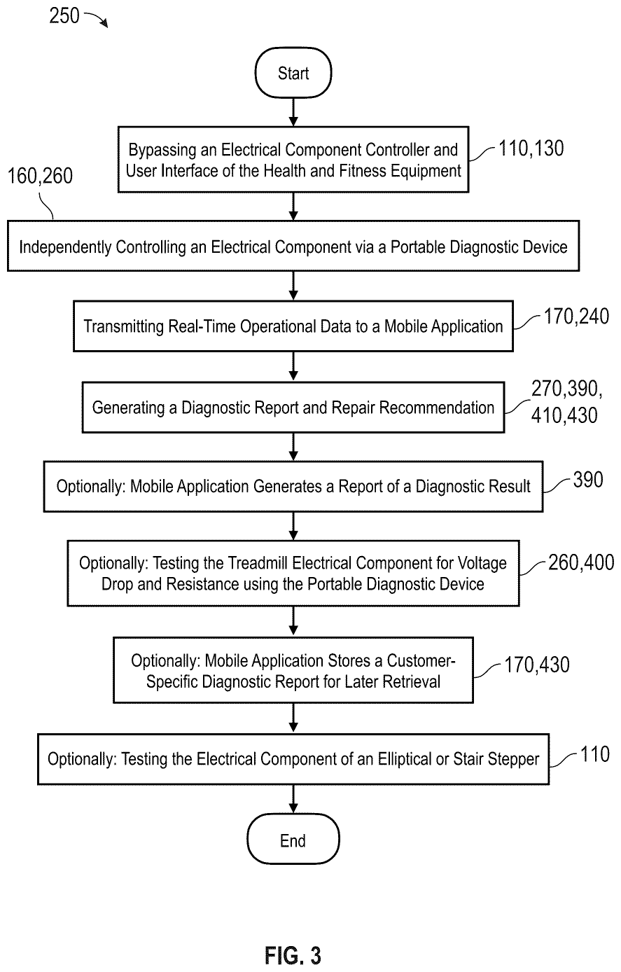

Referring to the Figures, there is shown in FIGS. 1, 2, and 3 the following features:
Element 100 which is a diagnostic system for health and fitness equipment.
Element 110 which is health and fitness equipment such as a treadmill, an elliptical, or a stair stepper.
Element 120 which is a control unit.
Element 130 which is an electrical component controller.
Element 140 which is a user console.
Element 150 which is a connection module.
Element 160 which is an electrical component such as a drive motor, an incline motor, an alternator, a pump, a battery, and/or a power cord.
Element 170 which is a mobile application.
Element 180 which is a physical diagnostic device for a health and fitness equipment.
Element 190 which is a portable case.
Element 200 which is an electrical component control board.
Element 210 which is a connection port.
Element 220 which is a data interface.
Element 230 which is a connected mobile device.
Element 240 which is a real-time operational data.
Element 250 which is a method for diagnosing a malfunction of a health and fitness equipment.
Element 260 which is a portable diagnostic device.
Element 270 which is a diagnostic report and repair recommendation based on captured data.
Element 280 which is a multimeter reading.
Element 290 which is a trend analysis functionality.
Element 300 which is an electrical component performance.
Element 310 which is a DC electrical connection.
Element 320 which is an AC electrical connection.
Element 330 which is a probe port.
Element 340 which is a standard multimeter probe.
Element 350 which is a power socket.
Element 360 which is a switch.
Element 370 which is a supply of electrical power.
Element 380 which is a variable speed control.
Element 390 which is a report of a diagnostic result.
Element 400 which is a treadmill electrical component.
Element 410 which is a repair suggestion based on amp draw and voltage data.
Element 420 which is a battery-powered health and fitness equipment.
Element 430 which is a customer-specific diagnostic report.
Element 440 which is a safety key mechanism and an emergency stop mechanism.
Element 450 which is a breaker for an overload protection.
Element 460 which is a programmable firmware for updating a testing protocol remotely.
Element 470 which is a display screen.

### How to Make the Invention

### 1. Components and Materials

Portable Enclosure: Select a durable and weather-resistant enclosure, such as an ammo can or custom-molded case with foam inserts to protect internal components during transport. The enclosure should have adequate ventilation to prevent overheating during operation. Include ergonomic handles or straps for portability.

Motor Control Board: Design a motor control board capable of handling multiple voltage ranges (e.g., 0 -90 VDC for DC motors and variable VAC for AC motors). Ensure the board has diagnostic feedback capabilities, such as monitoring current draw, voltage levels, and response signals. Incorporate programmable logic to adapt to different motor types and conditions.

Connection Ports:

DC Port: Include two high-current connectors (e.g., male spade or Anderson connectors) for DC motor testing. These should be robust enough to handle high-amperage loads.

AC Port: Provide three connectors for AC motor diagnostics with the ability to measure and control phase voltage.

Pot Port: Install three connectors to read potentiometer signals for incline and stride motor diagnostics, ensuring precise measurements.

Probe Ports: Add universal multimeter probe connectors to enable manual testing of voltage, resistance, and continuity.

Power Supply and Safety Mechanisms: Integrate a universal power supply capable of handling standard 110V/220V AC inputs. Include a power switch and a circuit breaker to protect the device from power surges or incorrect connections.

Microcontroller: Use a microcontroller (e.g., Arduino, STM32, or Raspberry Pi) to manage diagnostics and testing protocols. The microcontroller should support data collection, communication with the mobile app, and control of motor functions.

Wireless Connectivity (option): Add a Bluetooth or Wi-Fi module to enable wireless communication with a smartphone or tablet. In addition to or replacement for a connection to a smartphone or tablet via USB cable.

Firmware: Develop firmware for the microcontroller that includes: Diagnostic modes for DC and AC motors, alternators, and resistors. Testing protocols for measuring voltage, current, and resistance. Compatibility with health and fitness equipment-specific requirements.

### 2. Mobile Application

User Interface (UI): Create an intuitive interface with simple navigation. Include visual aids like step-by-step instructions, diagrams, and animated graphics to guide users through diagnostics.

Data Processing: Implement algorithms to analyze diagnostic data in real time. Include error-checking features to ensure accurate results. Provide explanations for identified issues and recommended repair actions.

Report Generation: Add functionality to compile test results into professional-grade PDF reports. Include sections for component condition, repair recommendations, and test logs.

Compatibility: Develop the app for both Android and iOS platforms. Use responsive design to ensure usability across devices with different screen sizes.

### 3. Assembly

Securely mount the motor control board, microcontroller, and power supply inside the enclosure.

Wire the connection ports to the motor control board with labeled connectors for easy identification.

Install the circuit breaker, power switch, and any necessary LEDs or indicators on the exterior of the enclosure.

Conduct thorough testing of all connections and features to ensure safety and functionality.

### How to Use the Invention

### 1. Setup

Position the diagnostic device near the health and fitness equipment to be tested.

Plug the device into a power outlet and turn it on using the integrated power switch.

Connect the device to the mobile application via Bluetooth or Wi-Fi.

### 2. Connecting Equipment

Disconnect the malfunctioning motor control board from the treadmill or other health and fitness equipment.

Connect the drive motor to the DC port and the incline motor to the AC port.

For potentiometer diagnostics, connect the motor's potentiometer wires to the Pot Port.

For general testing, use the probe ports for multimeter-like functionality.

### 3. Performing Diagnostics

Open the mobile application and select the equipment type (e.g., treadmill, elliptical, stepper) and component to be tested.

Follow the step-by-step instructions on the app: For DC motor testing, adjust speed settings via the app and observe data such as current draw, voltage, and resistance. For incline motor testing, initiate movement and monitor potentiometer readings to ensure proper operation. For alternators, apply a low-voltage kick to test electrical generation. For batteries, measure voltage levels and evaluate overall health.

### 4. Generating Reports

After testing, the mobile app automatically compiles the diagnostic data into a detailed report. The report includes: Test results with graphical data (e.g., voltage/current charts). Identified issues and their severity based on established industry standards. Repair recommendations and suggested parts or actions. Save the report in the app or export it as a PDF for sharing with clients or maintenance logs.

### 5. Trend Analysis and Predictive Maintenance

Use the trend analysis feature in the app to review historical data for specific components.

Identify patterns that may indicate wear or potential failures.

Schedule proactive repairs to prevent costly breakdowns and extend equipment lifespan.

### 6. Testing Other Equipment

Switch the device to the appropriate mode for the equipment being tested (e.g., elliptical stride motor, stepper resistance motor).

Follow similar diagnostic steps as outlined for treadmill components, tailored to the specific equipment type.

### Advantages of the Invention

Efficiency: Automates diagnostics, reducing technician effort and test time.

Versatility: Compatible with various health and fitness equipment, consolidating multiple diagnostic tools into one.

Reliability: Provides accurate, real-time data, minimizing human error.

Professional Reporting: Generates professional-grade reports, enhancing customer service and record-keeping.

Proactive Maintenance: Tracks performance trends to predict failures, ensuring better equipment reliability.

The present invention offers a transformative approach to diagnosing and maintaining health and fitness equipment, combining advanced hardware, intuitive software, and robust testing capabilities to meet the needs of professionals and home users alike.

### Options for the Invention

The TreadTester (DXT-P1) diagnostic system can be customized and adapted in several ways to meet different user needs, environments, and technological requirements. These options allow for flexibility in design, functionality, and usage, catering to both professional technicians and home users.

### Hardware Options

### Enclosure Design

Basic Option: A lightweight, durable plastic case for cost-conscious users, offering portability and protection in standard conditions.

Advanced Option: A ruggedized, weatherproof metal case (e.g., aluminum or steel) with enhanced durability for technicians operating in challenging environments such as outdoor facilities or high-humidity areas.

### Connection Ports

Basic Option: Standardized ports for DC motors and AC motors only, simplifying the device for treadmill-specific diagnostics.

Expanded Option: Additional ports for alternators, potentiometers, and multimeter probes, enabling diagnostics across a broader range of components and health and fitness equipment types.

### Power Supply

Standard Option: A 110/220V AC input power supply with an integrated circuit breaker for safety.

Battery-Powered Option: A built-in rechargeable lithium-ion battery for cordless operation, ideal for on-site diagnostics in remote locations.

### Connectivity

Wired Option: A USB connection for data transfer to a mobile application, providing a cost-effective and secure communication method.

Wireless Option: Bluetooth and Wi-Fi connectivity for seamless interaction with mobile devices, offering greater convenience and flexibility.

### Software Options

### Mobile Application Features

Basic Option: A simplified app for home users that provides guided testing workflows and real-time diagnostic results without advanced analytics.

Professional Option: A comprehensive app for technicians, including detailed diagnostic

Predefined Testing Modes: Specific modes for treadmills, ellipticals, and steppers, preset with common diagnostic parameters.

Customizable Testing Modes: Allow users to define their own parameters for unique or proprietary equipment.

### Integration with Cloud Services

Offline Mode: Diagnostics and reporting without the need for internet connectivity, with local storage on the mobile device.

Cloud-Enabled Option: Synchronization with cloud services for remote access to diagnostic results, sharing across teams, and long-term storage.

### Usage Scenarios

### Home Users

Simplified Interface: A basic version of the TreadTester with fewer connection ports and a streamlined app interface for DIY repairs and diagnostics of personal health and fitness equipment.

Cost-Effective Design: A more affordable option with plastic enclosures and USB connectivity.

### Professional Technicians

All-In-One Solution: A fully equipped device with expanded connection ports, wireless communication, and advanced diagnostic tools for multiple types of health and fitness equipment.

Enhanced Reporting: Tools to generate and share professional-grade reports for client communication and record-keeping.

### Gym Owners

Multi-Equipment Compatibility: A version designed to diagnose a variety of equipment, including treadmills, ellipticals, steppers, and bikes, to support diverse gym setups.

Predictive Maintenance Tools: Trend analysis and performance monitoring to proactively schedule repairs and minimize downtime.

Standard Testing Protocols: Preprogrammed firmware for common diagnostic tasks, such as motor speed and voltage testing.

Basic Logic: Simple on/off controls and basic motor testing algorithms.

Advanced Logic: Sophisticated diagnostic algorithms, such as fault isolation and real-time adaptive testing, to provide deeper insights into equipment performance.

### Accessory Options

### Testing Probes

Standard Probes: Basic probes for voltage and resistance testing.

Enhanced Probes: Insulated probes with built-in sensors for additional safety and accuracy.

### Cables and Connectors

Basic Cables: Fixed-length cables with standard connectors for basic use cases.

Modular Cables: Adjustable-length cables with interchangeable heads for compatibility with various equipment designs.

### Protective Accessories

Basic Carry Case: Lightweight carrying solutions for standard device protection.

Enhanced Kit: Includes a reinforced carrying case with compartments for cables, probes, and accessories.

### Licensing and Scalability

Provide subscription-based access for gym owners or repair businesses, including cloud storage, team management features, and priority customer support.

### Scalable Packages

Basic kits for smaller businesses with limited needs.

Enterprise-grade solutions for large-scale operations requiring diagnostics across multiple locations.

These options provide flexibility for designing and using the invention to meet the specific needs of various user groups, from individual home users to large-scale professional service providers. By offering different configurations, the invention can maximize its appeal and functionality across a broad range of applications.

In a preferred embodiment of the present invention, there is a diagnostic system for health and fitness equipment comprising a control unit configured to bypass the motor controller and user console of a treadmill. The system includes a connection module for interfacing with the treadmill's drive motor and incline motor and a mobile application operatively connected to the control unit. The mobile application is configured to display diagnostic steps, capture real-time testing data, and generate repair recommendations. The control unit facilitates the operation of the system even when critical components of the equipment, such as the motor controller, are non-functional, while the mobile application ensures a user-friendly interface for effective diagnostics.

In an alternate embodiment of the present invention, there is a diagnostic system in the form of a user interface within the mobile application for inputting multimeter readings. The user interface is designed with intuitive data entry fields and error-checking mechanisms to simplify data collection and improve diagnostic accuracy.

In an alternate embodiment of the present invention, there is a diagnostic system in the form of a trend analysis tool integrated into the mobile application. This tool tracks changes in motor performance metrics such as voltage and current over time, providing users with predictive maintenance insights and preventing equipment failures.

In an alternate embodiment of the present invention, there is a diagnostic system in the form of a connection module with separate ports for DC and AC motor testing. The connection module includes robust connectors capable of handling high current loads, ensuring compatibility with diverse motor types and allowing for safe and efficient diagnostics.

In a preferred embodiment of the present invention, there is a physical diagnostic device for health and fitness equipment comprising a motor control board housed within a portable enclosure. The motor control board is configured to independently operate treadmill drive motors and incline motors. The device includes multiple connection ports for attaching DC motors, AC motors, alternators, potentiometers, and resistors. It further incorporates a data interface, such as a USB or Bluetooth module, for transmitting real-time diagnostic data to a mobile application. The portable enclosure is designed for durability and ease of transport, allowing technicians to perform diagnostics in various environments.

In an alternate embodiment of the present invention, there is a diagnostic device in the form of a probe port for attaching standard multimeter probes. These ports provide additional diagnostic functionality for measuring voltage, resistance, and continuity in various components, enhancing the versatility of the device.

In an alternate embodiment of the present invention, there is a diagnostic device in the form of a portable case designed to protect internal components and provide ease of use. The case includes reinforced edges, ventilation openings, and an ergonomic handle for field operations, ensuring durability and operator convenience.

In an alternate embodiment of the present invention, there is a diagnostic device in the form of a breaker integrated into the power supply system to provide overload protection during testing. The breaker prevents damage to the device and connected health and fitness equipment by interrupting power flow in the event of an electrical surge or improper connection.

In a preferred embodiment of the present invention, there is a method for diagnosing health and fitness equipment malfunctions comprising bypassing the motor controller and user interface of a treadmill, independently controlling the drive motor and incline motor via a portable diagnostic device, and transmitting real-time operational data to a mobile application. The method further includes steps for generating detailed diagnostic reports and repair recommendations, enabling users to identify and resolve issues with health and fitness equipment efficiently.

In an alternate embodiment of the present invention, there is a method in the form of a process for generating PDF reports. This process organizes diagnostic results, including motor performance data and identified faults, into professional-grade documents that can be stored or shared with clients.

In an alternate embodiment of the present invention, there is a method in the form of a testing procedure for measuring voltage drop and resistance in treadmill motors. This procedure involves applying a controlled current and monitoring the response, allowing users to assess the condition of the motor and diagnose potential faults accurately.

In an alternate embodiment of the present invention, there is a method in the form of a data storage feature integrated into the mobile application. This feature enables users to save diagnostic reports and historical performance data for each piece of equipment, facilitating long-term maintenance planning and performance tracking.

The present invention can also include an OBD-II-type diagnostic feature through the integration of a QuickFIT Quick Full Information Transfer (QuickFIT) device. QuickFIT will be the protocol, Full Information Transfer Port (FITPort) will be the physical device, which is an aftermarket component designed to streamline the diagnostic process for health and fitness equipment, particularly treadmills, in environments requiring frequent servicing. This enhancement significantly improves the efficiency of diagnostics for operators such as gym owners or maintenance technicians, who must routinely test multiple units.

The FITPort device serves as an installed connection point within health and fitness equipment, allowing the TreadTester (TT+) diagnostic device to plug in seamlessly for rapid diagnostics. The OBD-II-type port facilitates simplified connections for routine maintenance, protects the equipment's motor control board (MCB) during diagnostics, and accelerates transitions between multiple machines.

The QuickFIT device may include a diode to ensure voltage flows only to the components being tested, preventing backflow to the treadmill's MCB. This ensures the safety of sensitive internal electronics during diagnostics. The device is constructed with durable materials to withstand repeated use in high-demand environments such as gyms and fitness centers.

### Design and Construction of the QuickFIT Device

The QuickFIT device includes a robust connector harness with multiple connection points for interfacing with key treadmill components such as the drive motor, incline motor, and potentiometers. The diode is integrated into the circuit to isolate voltage flow, allowing safe operation during testing.

The FITPort device features an OBD-II-type port compatible with the TT+ diagnostic device. The port includes secure locking mechanisms to ensure stable connections during testing. The connector harness and port are designed to support high-current applications and repeated connections over time.

The QuickFIT harness is designed for operator installation, requiring the technician to attach the harness to the treadmill's internal components and mount the port in an accessible location on the equipment frame. This installation process ensures that the QuickFIT system remains available for routine diagnostics.

### How the QuickFIT Feature Enhances the Invention

The QuickFIT feature streamlines the diagnostic process by eliminating the need for technicians to manually connect and disconnect individual components for testing. The TT+ device plugs directly into the FITPort port, enabling rapid diagnostics of each machine in a sequence.

For facilities with numerous health and fitness machines, the QuickFIT feature reduces maintenance labor and downtime significantly. Operators can efficiently diagnose all machines by moving the TT+ device from one FITPort port equipped machine to the next, saving time and effort.

The diode within the QuickFIT device ensures safe operation by preventing voltage backflow into the treadmill's MCB, thereby protecting sensitive electronics and prolonging the equipment's lifespan.

While primarily designed for treadmills, the QuickFIT feature can be adapted for other heath and fitness equipment types such as ellipticals or steppers. This flexibility expands the application of the invention to a broader range of diagnostic scenarios.

### Technical Specifications of the QuickFIT Feature

The FITPort harness includes connection points for DC motor testing, AC motor diagnostics, potentiometer readings, speed sensor readings, and other readings and/or measurements. These connections are designed for high durability and compatibility with standard health and fitness equipment configurations.

The QuickFIT port features an OBD-II-style interface with a locking mechanism for secure and reliable operation. It is robust enough to withstand frequent use in commercial environments.

The diode integrated into the QuickFIT circuit ensures voltage isolation, allowing the diagnostic system to safely test components without risk of damage to the treadmill's internal systems.

Installation of the QuickFIT device requires basic electrical skills and involves connecting the harness to the treadmill's internal components, securing the port on the equipment frame, and verifying operational functionality.

### Use Case Example

A gym owner installs the FITPort port on all treadmills in the facility. Each FITPort harness is connected to the treadmill's drive motor, incline motor, potentiometers, and/or other internal components.

The technician connects the TT+ device to the FITPort port of tread #1, runs diagnostics using the mobile app, and captures data for each component. Once testing is complete, the technician moves to tread #2, plugs into its FITPort port, and repeats the process.

This streamlined approach reduces the time required for diagnostics and maintenance, ensuring that all machines are tested efficiently and consistently.

### Advantages of the QuickFIT Feature

The QuickFIT system significantly reduces diagnostic time, allowing technicians to move rapidly between machines without manually reconnecting components.

The simplified plug-and-play operation eliminates tedious setup steps, making diagnostics faster and more user-friendly.

The integrated diode ensures that voltage is safely isolated from the treadmill's MCB, protecting sensitive internal electronics during diagnostics.

The durable design and robust connection points ensure reliable performance in high-demand environments, such as gyms and fitness centers.

By enabling faster and safer diagnostics, the QuickFIT feature enhances the overall utility and versatility of the TreadTester (TT+) diagnostic system, making it an indispensable tool for health and fitness equipment maintenance.

The present invention, a diagnostic system and method for health and fitness equipment, offers a range of innovative advantages that address significant limitations in the current state of the art. These advantages enhance the efficiency, accuracy, and ease of maintaining and repairing health and fitness equipment while providing users with tools for predictive maintenance and professional-grade reporting.

### Enhanced Diagnostic Capabilities

Bypassing Malfunctioning Motor Control Boards: The invention allows independent testing of components such as drive motors, incline motors, alternators, and potentiometers, even when the motor control board is non-functional. This capability eliminates a critical bottleneck in traditional diagnostics, where non-functional control boards often prevent further testing.

Multi-Equipment Compatibility: Unlike existing diagnostic tools that are often limited to treadmills, the present invention supports a wide range of health and fitness equipment, including ellipticals, steppers, and bikes. This versatility makes it a comprehensive solution for gyms, repair technicians, and home users.

### Automation and Ease of Use

Mobile Application Integration: The invention's mobile application provides guided diagnostic workflows, real-time data visualization, and automated repair recommendations. This simplifies the process for users of all experience levels, reducing the need for technical expertise and minimizing errors.

Step-by-Step Guidance: The app offers clear instructions, visual aids, and error-checking features that walk users through the testing process, ensuring consistent and accurate diagnostics.

Plug-and-Play Design: The physical diagnostic device is designed for easy setup and operation, with labeled connection ports and intuitive interfaces that allow users to quickly begin testing.

### Efficiency and Time Savings

Streamlined Testing: By automating diagnostic steps and eliminating the need for manual data entry, the invention reduces testing time significantly. This allows technicians to diagnose and repair equipment more efficiently, increasing productivity.

Real-Time Data Analysis: The system processes diagnostic data in real time, providing immediate insights into equipment performance and highlighting potential issues without the need for post-testing analysis.

### Professional-Grade Reporting

Automated Report Generation: The invention produces detailed PDF reports that include diagnostic results, repair recommendations, and graphical data such as voltage and current trends. These reports are professional-grade and can be shared with clients, stored for maintenance logs, or used for warranty claims.

Customizable Branding: For professional technicians and service providers, the reports can be customized with branding, enhancing their professional image and client communication.

### Predictive Maintenance

Trend Analysis Tools: The mobile application tracks historical performance data, enabling users to identify patterns that may indicate wear or impending failures. This proactive approach helps prevent costly breakdowns and extends equipment lifespan.

Preventative Repairs: By identifying potential issues early, the invention allows users to schedule repairs before failures occur, minimizing downtime and maintaining equipment reliability.

### Safety and Reliability

Overload Protection: The integrated circuit breaker ensures safe operation of the diagnostic device and connected health and fitness equipment, preventing damage from power surges or misconnections.

Error-Checking Mechanisms: Built-in error detection in the firmware and mobile application minimizes user mistakes during diagnostics, ensuring consistent and reliable results.

### Portability and Flexibility

Rugged and Portable Design: The physical device is enclosed in a durable, lightweight case that is easy to transport. This makes it suitable for use in diverse environments, from professional workshops to on-site repairs.

Cordless Operation Option: A rechargeable battery-powered version of the device provides flexibility for technicians working in remote locations or areas without reliable power sources.

### Scalability and Adaptability

Customizable Testing Modes: The firmware and mobile application can be updated to support new equipment types or specific diagnostic needs, ensuring that the invention remains relevant as health and fitness equipment technology evolves.

Cloud Integration: An optional cloud-enabled version allows users to store and access diagnostic data remotely, facilitating team collaboration and long-term data management.

### Broad User Appeal

For Professional Technicians: The invention offers a comprehensive toolset for diagnosing and repairing health and fitness equipment across multiple models and brands, increasing their service efficiency and customer satisfaction.

For Gym Owners: Predictive maintenance features help reduce equipment downtime, improve operational reliability, and enhance member satisfaction.

For Home Users: The simplified version of the invention provides an easy-to-use solution for DIY diagnostics, reducing repair costs and extending the life of personal health and fitness equipment.

### Environmental and Economic Benefits

Reduced Waste: By enabling precise diagnostics and targeted repairs, the invention reduces unnecessary replacement of functional components, minimizing waste.

Cost Savings: Proactive maintenance and accurate diagnostics lower repair costs by addressing issues before they escalate, benefiting both individual users and commercial facilities.

The invention has been described by way of examples only. Therefore, the foregoing is considered as illustrative only of the principles of the invention. Further, since numerous modifications and changes will readily occur to those skilled in the art, it is not desired to limit the invention to the exact construction and operation shown and described, and accordingly, all suitable modifications and equivalents may be resorted to, falling within the scope of the claims.

Although the invention has been explained in relation to various embodiments, it is to be understood that many other possible modifications and variations can be made without departing from the spirit and scope of the invention.

1-20. (canceled)

21. A diagnostic system for health and fitness equipment, comprising:
(a) a portable external control unit configured to electrically isolate and bypass a native electrical component controller and a user console of said health and fitness equipment by disconnecting said native electrical component controller from at least one electrical component of said health and fitness equipment;
(b) a connection module comprising a plurality of external electrical connection ports configured to electrically couple directly to said at least one electrical component after disconnection of said native electrical component controller, said at least one electrical component including a drive motor and an incline motor, said plurality of external electrical connection ports including a DC electrical connection port configured to supply DC operating power to said drive motor during diagnostic testing and an AC electrical connection port configured to supply AC operating power to said incline motor during diagnostic testing, wherein said portable external control unit is configured to independently operate said at least one electrical component under diagnostic load conditions without reliance on said native electrical component controller; and
(c) a mobile application operatively connected to said portable external control unit and configured to receive real-time electrical performance data including current draw, voltage, and resistance and generate a diagnostic report and a repair recommendation.

22. A portable external diagnostic device for health and fitness equipment, comprising:
(a) an electrical component control board housed within a portable enclosure, said electrical component control board being configured to electrically isolate and replace a native electrical component controller during diagnostic testing;
(b) a plurality of external electrical connection ports including a DC motor port comprising high-current connectors and an AC motor port; and
(c) a data interface configured to transmit electrical performance data obtained during diagnostic operation.

23. A method for diagnosing a malfunction of health and fitness equipment, comprising:
(a) disconnecting a native electrical component controller from at least one electrical component;
(b) electrically coupling a portable external diagnostic device directly to said at least one electrical component;
(c) independently operating said at least one electrical component under diagnostic load conditions;
(d) measuring electrical performance parameters including current draw, voltage, and resistance; and
(e) generating a diagnostic report and a repair recommendation based on a plurality of measured electrical performance parameters.

24. The diagnostic system of claim 21, wherein said mobile application includes a user interface for inputting a multimeter reading obtained from said at least one electrical component being independently operated by a diagnostic device.

25. The diagnostic system of claim 21, further comprising a trend analysis function configured to track said real-time electrical performance data of said at least one electrical component over time.

26. The diagnostic system of claim 21, wherein said connection module includes separate ports for a DC electrical connection and an AC electrical connection configured to supply operating power during diagnostic testing.

27. The portable external diagnostic device of claim 22, further comprising a probe port for attaching a standard multimeter probe.

28. The portable external diagnostic device of claim 22, wherein said portable enclosure comprises an ammunition can configured to provide physical protection and electrical isolation.

29. The portable external diagnostic device of claim 22, further comprising a power socket and a switch for controlling delivery of electrical power during diagnostic operation.

30. The portable external diagnostic device of claim 22, wherein said electrical component control board provides variable speed control for diagnostic evaluation.

31. The diagnostic system of claim 21, wherein said connection module comprises a QuickFIT harness configured to mate with a FITPort installed within said health and fitness equipment.

32. The method of claim 23, further comprising testing said at least one electrical component for voltage drop and resistance while said at least one electrical component is operated under load.

33. The diagnostic system of claim 21, wherein said mobile application generates said repair recommendation based on amp draw and voltage data.

34. The diagnostic system of claim 21, wherein said portable external control unit includes said DC electrical connection port for testing battery-powered health and fitness equipment.

35. The method of claim 23, wherein said mobile application stores a customer-specific diagnostic report for later retrieval.

36. The diagnostic system of claim 21, further comprising testing an emergency stop mechanism including a safety key mechanism.

37. The portable external diagnostic device of claim 22, further comprising a breaker providing overload protection.

38. The diagnostic system of claim 21, wherein said health and fitness equipment includes a treadmill, an elliptical trainer, and a stair stepper.

39. The method of claim 23, further comprising diagnosing said at least one electrical component of an elliptical trainer or a stair stepper.

40. The portable external diagnostic device of claim 22, wherein said electrical component control board includes programmable firmware for remotely updating diagnostic testing protocols.

41. The diagnostic system of claim 21, wherein said health and fitness equipment is not connected to an electric power source.

42. The portable external diagnostic device of claim 22, wherein said health and fitness equipment is not connected to an electric power source.
